(19) United States
(12) Patent Application Publication
(10) Pub. No.: US 2009/0002056 A1
(43) Pub. Date: Jan. 1, 2009

(54) ACTIVE RESISTANCE CIRCUIT WITH CONTROLLABLE TEMPERATURE COEFFICIENT

(76) Inventors: James T. Doyle, Prescott, AZ (US); William Jiang, Cupertino, CA (US)

Correspondence Address: INTEL CORPORATION;c/o INTELLEVATE, LLC, P.O. BOX 52050, MINNEAPOLIS, MN, 55402, US

(21) Appl. No.: 11/772,190

(22) Filed: Jun. 30, 2007

(51) Int. Cl. H01L 37/00

(52) U.S. Cl. 327/512

(57) ABSTRACT

Embodiments of the invention provide a circuit to implement an on-chip resistor with desired temperature coefficient behavior. In some embodiments, a circuit may comprise an amplifier, with a reference controlled by ratioed amounts of one or more positive temperature coefficient (TC+) and/or negative temperature coefficient (TC−) circuits, coupled to a controllable resistor device to control it as temperature changes to track the desired temperature coefficient behavior.

### BACKGROUND

The present invention relates to a circuit to provide a resistor with a controllable (or adjustable) temperature coefficient. Such a device may be employed in various applications including but not limited to an on-chip DCR resistance for sensing current in a phase of a voltage regulator.

FIG. 1 shows a conventional circuit for sensing current in a VR (voltage regulator) using a DCR (direct current resistance) methodology. It senses current in a VR phase through a phase leg inductor L by using the inductor's parasitic equivalent DC resistance R_{DCR}. It uses a resistor R1 and capacitor C1 coupled across the inductor L to generate a sense voltage V_{S} that is proportional to the current in the inductor. Also included is a resistor network formed from resistors R2, R3 and thermistor R_{T} to compensate for R_{DCR} changes resulting from changes in temperature. Traditionally, thermistors have been used to provide this compensation because on-chip resistor coefficients are limited and in many cases, negative temperature coefficient may not even be available. Accordingly, an improved solution is desired.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a conventional DCR current sensing circuit.

FIG. 2 is a schematic diagram of an active TC resistor circuit coupled to a DCR current sensing circuit in accordance with some embodiments.

FIG. 3 is a positive temperature coefficient circuit suitable for use with the TC resistor circuit of FIG. 2 in accordance with some embodiments.

FIG. 4 is a diagram of a negative temperature coefficient circuit suitable for use with the TC resistor circuit of FIG. 2 in accordance with some embodiments.

FIG. 5A is a diagram of a controllable variable resistor device suitable for use with the TC resistor circuit of FIG. 2 in accordance with some embodiments.

FIG. 5B is a diagram of a controllable variable resistor device suitable for use with the TC resistor circuit of FIG. 2 in accordance with some other embodiments.

### DETAILED DESCRIPTION

Embodiments of the invention provide a circuit to implement an on-chip resistor with desired temperature coefficient behavior. In some embodiments, a circuit may comprise an amplifier, with a reference controlled by ratioed amounts of one or more positive temperature coefficient (TC+) and/or negative temperature coefficient (TC−) circuits, coupled to a controllable resistor device to control it as temperature changes to track the desired temperature coefficient behavior.

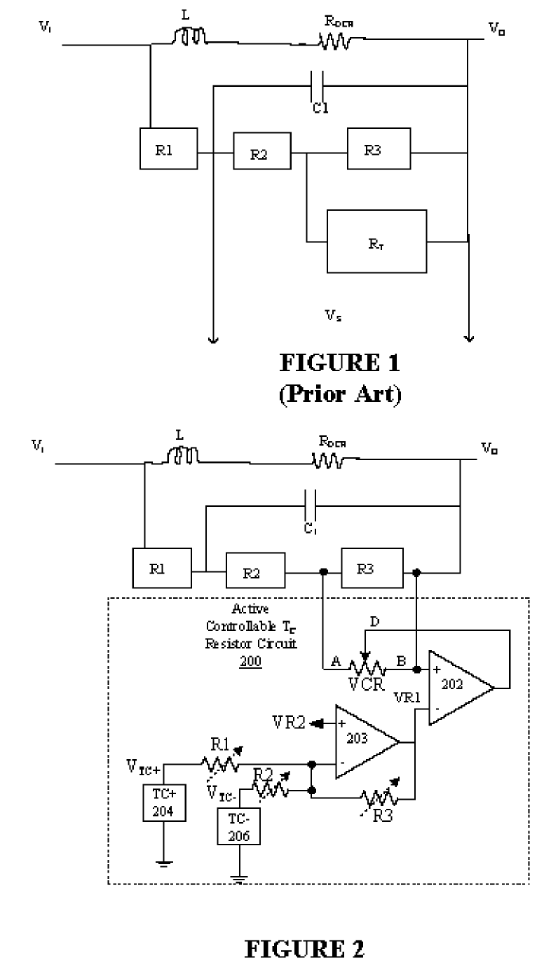

FIG. 2 shows an active resistor circuit 200 with a controllable T_{C}, coupled to the DCR current sensing circuit of FIG. 1, in accordance with some embodiments. The DCR current sensing circuit, rather than using a thermistor (R_{T}) in this embodiment, instead, employs a voltage controlled resistor device (VCR) controlled to track desired temperature coefficient behavior, e.g., temperature coefficient of the inductor's parasitic resistance R_{DCR}.

The circuit 200 generally comprises a differential amplifier 202, voltage controlled resistor VCR, differential amplifier 203, resistors R1 to R#, positive temperature coefficient (TC+) circuit 204, and negative temperature coefficient (TC−) circuit 206, all coupled together as shown. Amplifiers 202, 203 may be implemented with any suitable amplifier, e.g., a relatively high gain differential amplifier. Differential amplifier 202 is configured, in cooperation with the voltage controlled resistor (VCR) for closed loop operation with unity gain. (In the depicted embodiment, as the resistance of the VCR increases, it causes the voltage at the non-inverting node to decrease, thereby resulting in closed-loop feedback.) The amplifier 202 controls the VCR with a control voltage that is determined by a coefficient reference voltage (VR₁) at the amplifier's inverting input, which, due to the closed loop nature of the circuit, is projected to the non-inverting input, as well as to its output (since their is unity gain in this embodiment) to control the VCR.

Amplifier 203, in cooperation with resistors R1 to R3, make up a summing voltage amplifier (as is well known in the art). The summing amplifier output (VR1) is inversely proportional to the sum of V_{TC}+(R3/R1)+V_{TC-}(R3/R2). (Note that the output is also dependent on VR2 terms, which have been left out for simplicity since they don't alter the linear summing nature of the circuit. The value of VR2 could be any desired value, but a positive value, e.g., between the rails of amplifier 203, may be used to avoid the need for a negative supply.) It can be seen that by selecting suitable values for resistors R1 and R2, the contributive weights of VTC+ and VTC− can be controlled, as appreciated below for attaining an overall temperature coefficient response for VCR.

(Note that the dotted arrows in the resistors, here and in following figures, indicate that these resistors may be trimmable so that their values can be tuned, e.g., during the manufacturing process. In some embodiments, gang trimming of all resistors at the same time to provide an accurate and precise initial starting point could be implemented. For example, with process variations on chip typically occurring in the same way at the same time, the resistors may be commonly trimmed based on an external precision resistor.)

The TC+ circuit 204 produces the voltage (V_{TC+}) at an increased level with increased temperature, thereby reducing VR1, which causes the resistance of the VCR to increase with temperature. Conversely, the TC− circuit 206 produces V_{TC-}, which decreases with temperature thereby raising VR1 and thus causing the resistance of the VCR to decrease as temperature increases. The relative weights of V_{TC+} and V_{TC-} can be controlled, respectively, with the values of R1 and R2, which inversely contribute to the magnitude of the output (VR1) from amplifier 203. That is, the relative contribution of VTC+ can be increased by decreasing R1 relative to R2, or conversely, the relative value Of V_{TC-} could be increased by decreasing R2 relative to R1.

The values can be set so that TC+ and TC− cause amplifier 202 to control the VCR to have a desired overall temperature coefficient behavior. For example, the TC+ circuit could have an associated TC of 3300 PPM with a relative weight of 67%, while the TC− circuit could have a an associated temperature coefficient of −1000 PPM with a relative weight of 33%. This would result in the VCR having an overall TC of about 2200−330=1870 PPM. Accordingly, it can be seen that almost any desired overall TC may be achieved by using one or more TC+ circuits with appropriate weights and/or one or more TC-circuits with appropriate weights.

(Note that the temperature coefficient, TC+, TC−, circuits may be implemented with any suitable circuits for having desired TC effects on the overall TC of the VCR. For example, most traditional PTAT circuits could be used for a TC+ 204 circuit and most traditional CTAT circuits could be used for a TC− circuit 206, depending on how the circuitry is arranged. Moreover, different combinations of circuits may provide linear temperature coefficients, exponential, or other combinations of desired temperature coefficient behavior. Furthermore, while a voltage summing circuit is shown, persons of skill will appreciate that a current summing circuit or some other suitable circuit for combining the TC+ and TC− circuits could be used to generate the VR1 reference with desired T_{C} tracking characteristics.)

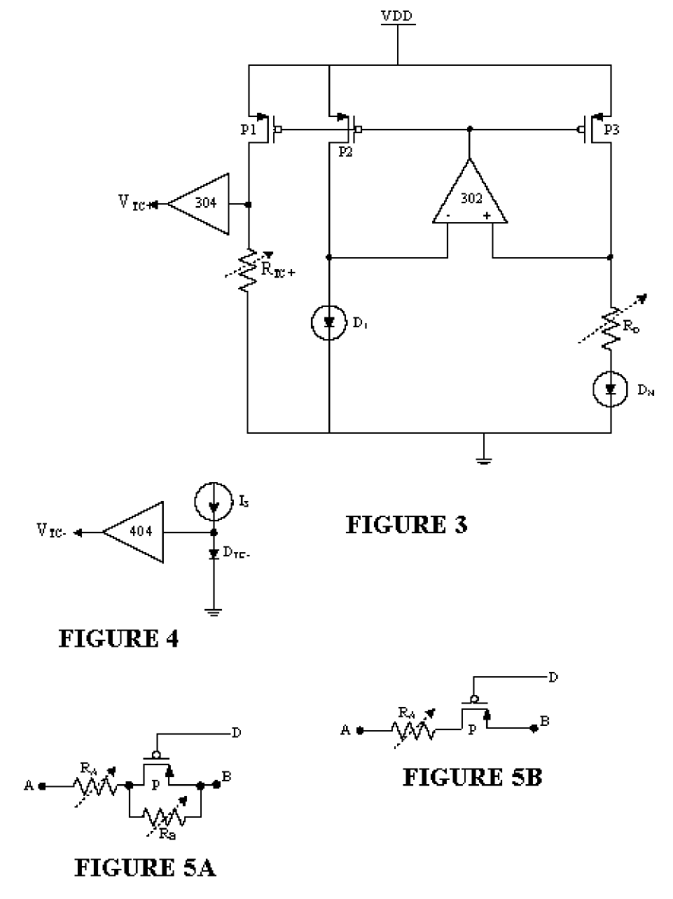

FIG. 3 shows an exemplary TC+ circuit suitable for use as circuit 204. It is formed from a conventional PTAT type circuit and comprises diodes D1, DN, differential amplifier 302, buffer amplifier 304, PMOS type transistors P1 to P3, and resistors R_{D} and R_{TC+}, all coupled together as shown. The amplifier 302 and P-type transistors are configured to provide the amplifier with negative feedback so that the voltages at the inverting and non-inverting nodes approach being equal to one another. Diode D_{N} is N times larger than diode D1. Thus, there is a voltage difference imposed across resistor R_{D} that is proportional to the temperature of the circuit. As temperature increases, it causes the drop to increase, which results in a proportional increase in current through transistor P3. This current is mirrored through transistor(s) P1. The current from P1 is fed into reference transistor R_{TC+}, which generates a voltage (V_{TC+}) out of buffer 304 that is proportional to temperature.

FIG. 4 shows an exemplary circuit for implementing a TC− circuit such as TC− circuit 206. It is formed from a conventional CTAT circuit comprising a current source I_{S} coupled in series to a diode D_{TC-} as shown. At the junction of the current source and diode, a voltage (CTAT voltage) inversely proportional to temperature is generated. This voltage is buffered through buffer 404 and provided as V_{TC-} in the circuit of FIG. 2.

The VCR may be implemented with any suitable circuit to provide a resistance that can suitably be controlled by an amplifier in a TC circuit such as circuit 200. FIGS. 5A and 5B show exemplary VCR circuits that comprise a transistor (PMOS transistor in this embodiment) with a series resistor R_{A} and a parallel coupled resistor R_{B} in the case of the circuit of FIG. 5B. Based on the operating range of the control voltage (corresponding to the operating range of V_{Ref}), the circuits are configured so that their transistors operate in the linear (triode) regions. In this way, a continuous variable resistance may be provided. The resistors help to keep the transistors in the triode regions. In some embodiments, additional transistors, coupled in series with the depicted transistor, could be employed to provide a greater triode-region operating range.

Note that with respect to the DCR application, discussed above, the design can be adaptive and determine the external series resistance and adjust the VCR accordingly. For example, the learning process could be as simple as applying a constant current to the inductor and measuring the voltage during startup.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
an amplifier coupled to a variable resistor device to control its resistance; and
one or more temperature coefficient circuits coupled to the amplifier to cause it to control the variable resistor device in accordance with a desired temperature coefficient behavior.

2. The chip of claim 1, in which the one or more temperature coefficient circuits comprise at least one weighted positive temperature coefficient circuit.

3. The chip of claim 2, in which the one or more temperature coefficient circuits comprise at least one weighted negative temperature coefficient circuit.

4. The chip of claim 3, in which the positive temperature coefficient circuit is formed from a PTAT circuit.

5. The chip of claim 3, in which the negative temperature coefficient circuit is formed from CTAT circuit.

6. The chip of claim 1, in which the one or more temperature coefficient circuits are coupled to a reference node of the amplifier.

7. The chip of claim 1, in which the variable resistor device comprises a voltage controlled resistor (VCR).

8. The chip of claim 7, in which the VCR comprises a MOS type transistor coupled to a resistor.

9. The chip of claim 1, in which the variable resistor device is to be used for temperature compensation in a current sensing network for a voltage regulator.

10. A chip, comprising:
a controllable variable resistor in a circuit to sense current in a phase of a voltage regulator, the controllable variable resistor having a desired temperature coefficient behavior;
an amplifier coupled to the controllable variable resistor to control its resistance; and
one or more temperature coefficient circuits coupled to the amplifier to cause it to control the variable resistor in accordance with the desired temperature coefficient behavior.

11. The chip of claim 10, in which the one or more temperature coefficient circuits comprises at least one weighted positive temperature coefficient circuit.

12. The chip of claim 11, in which the one or more temperature coefficient circuits comprises at least one weighted negative temperature coefficient circuit.

13. The chip of claim 12, in which the positive temperature coefficient circuits are formed from PTAT circuits.

14. The chip of claim 12, in which the negative temperature coefficient circuits are formed from CTAT circuits.
